(19) United States
(12) Patent Application Publication
(10) Pub. No.: US 2026/0315990 A1
(43) Pub. Date: Oct. 15, 2026

(54) NOx REDUCTION

(71) Applicant: Edwards Limited, Burgess Hill, Sussex (GB)

(72) Inventor: James Hann, Clevedon, Somerset (GB)

(21) Appl. No.: 19/109,410

(22) PCT Filed: Aug. 31, 2023
(86) PCT No.: PCT/GB2023/052254

§ 371 Date: Mar. 6, 2025

(30) Foreign Application Priority Data
Sep. 9, 2022 (GB) 2213193.2

(51) Int. Cl. B01D 53/04; B01D 53/14; B01D 53/86

(52) U.S. Cl. CPC B01D 53/0462; B01D 53/0438; B01D 53/0454; B01D 53/1456; B01D 53/8631; B01D 53/8696; B01D 2253/1124; B01D 2257/404; B01D 2259/40056

(57) ABSTRACT

The present invention relates to an exhaust treatment system for NOx abatement of an exhaust stream. The exhaust treatment system comprises at least one NOx adsorber configured to adsorb NOx from the exhaust stream, and a NOx reactor operable in an offline configuration and an online configuration. When the NOx reactor is in an offline configuration, the NOx reactor is fluidly disconnected from the exhaust stream and the NOx adsorber, and the NOx adsorber is fluidly connected to the exhaust stream such that NOx contained in the exhaust stream may be adsorbed by the NOx adsorber. When the NOx reactor is in an online configuration, the NOx reactor is fluidly connected to the NOx adsorber such that NOx adsorbed by the NOx adsorber may be treated by the NOx reactor.

### CROSS-REFERENCE OF RELATED APPLICATION

This application is a Section 371 National Stage Application of International Application No. PCT/GB2023/052254, filed Aug. 31, 2023, and published as WO 2024/052646 A1 on Mar. 14, 2024, the content of which is hereby incorporated by reference in its entirety and which claims priority of British Application No. 2213193.2, filed Sep. 9, 2022.

### FIELD

The present invention relates to exhaust treatment systems for NOx abatement from an exhaust stream of a process tool, and to methods of abating NOx from an exhaust stream.

### BACKGROUND

Nitrogen oxides (NOx) are air pollutants, produced as a by-product of many processes, including burning of fossil fuels, and the production of semiconductors. NOx can be responsible for photochemical smog and acid rain, therefore, the release of NOx into the atmosphere must be limited and preferably avoided altogether. This is complicated by several challenges associated with the abatement of exhaust streams containing NOx, particularly in the presence of oxygen and/or water vapour.

NOx reactors, such as catalysts, are typically used in NOx abatement processes. High NOx abatement rates via a NOx reactor typically requires reductant-rich conditions, so the presence of oxygen in the exhaust stream may reduce the efficiency of abatement reactions. However, for many applications, the presence of oxygen and/or water in the exhaust stream is largely unavoidable. Addition of reducing agents, such as ammonia, is often used to facilitate the reaction of NOx providing a reaction which is feasible in the presence of oxygen or water. However, for many applications the use of ammonia is undesirable, since it is an additional consumable reagent which must be dosed.

A more preferable NOx abatement route would be to make use of reducing agents already present in the exhaust stream. For example, unoxidised/partially oxidised hydrocarbons and/or carbon monoxide (CO). However, the presence of oxygen in the exhaust stream when such reducing agents are used can be detrimental, as the reaction of O₂ with CO consumes much of the CO required for the reaction between CO and NO. In plasma NOx reactors, the presence of oxygen and/or water in the exhaust stream may also be undesirable, as it may result in pore blocking. Furthermore, the presence of O2 may enable nitric oxide to be converted to nitrogen dioxide, which should be avoided due to the associated health concerns if inhaled.

A further challenge to achieving efficient NOx abatement is presented by the deficiency of suitable direct NOx catalysts, so-called because they can directly decompose NOx without the need for a reducing agent. Although some direct NOx catalysts are available, few provide high enough activity to allow use of a suitably small volume of the catalyst to be appropriate for many industries. For example, in the semiconductor industry, the footprint of the exhaust treatment system is often limited. The overall size of the exhaust treatment system thereby restricts the overall volume of catalyst that can be used. Additionally, many direct NOx catalysts operate more efficiently at elevated temperatures, for example temperatures greater than 200° C. The operating cost required to maintain a large volume of catalyst at such high temperatures renders them unfeasible for practical application in many industries. Furthermore, the pressure drop associated with using large volumes of catalyst may be too great for many applications, particularly if the catalyst is placed directly into the exhaust of the chemical process.

Certain applications, such as the abatement of exhaust streams from process tools used in semiconductor manufacture, may provide particularly challenging conditions for NOx abatement. Water vapour may be present in the exhaust stream due to the burning of hydrocarbons, and/or water scrubbing processes upstream of the NOx reactor. This water vapour may deactivate the NOx reactor (e.g. catalyst). Certain catalysts, such as Cu-ZSM5 catalysts, may be permanently degraded by water vapour present in the exhaust stream. Additionally, the exhaust streams from semiconductor manufacture often contain a net oxidising amount of oxygen in relation to the total concentration of reductants available, thereby lessening the efficiency of the NOx decomposition. Also, particulate matter, such as silica, may be present in the exhaust stream and can foul the NOx reactor and/or reduce its activity. The pressure drop across the NOx reactor may be required to be low, imposing further constraints on such abatement systems.

A further challenge is posed by variation in the concentration of NOx within the exhaust stream according to the step of the semiconductor manufacture process that is occurring. For example, the NOx concentration in the exhaust stream may be relatively low during deposition processes. Then, the NOx concentration in the exhaust stream may be relatively high during a “clean-step” using NF₃. The “clean-step” typically occurs for a shorter time than the deposition processes. Accordingly, the NOx reactor may be required to abate high concentrations of NOx for a relatively short amount of time, then be substantially inactive or slightly active for long periods of time. Therefore, a NOx reactor must be selected that can meet the abatement requirements during the peak concentration of NOx, in spite of it's relatively short duration. This problem may be exacerbated by the relatively high overall gas flow through the exhaust treatment system.

It would therefore be beneficial to have an exhaust treatment system capable of operating under such conditions with reduced deactivation of the NOx reactor. The present invention aims to solve, at least in part, these and other problems associated with exhaust treatment systems of the prior art.

The discussion above is merely provided for general background information and is not intended to be used as an aid in determining the scope of the claimed subject matter. The claimed subject matter is not limited to implementations that solve any or all disadvantages noted in the background.

### SUMMARY

In an aspect, the present invention provides an exhaust treatment system for NOx abatement of an exhaust stream. The exhaust treatment system comprises at least one NOx adsorber configured to adsorb NOx from the exhaust stream. The exhaust treatment system further comprises a NOx reactor having an offline configuration and an online configuration. When the NOx reactor is in an offline configuration, the NOx reactor is fluidly disconnected from the exhaust stream and the NOx adsorber. Also, the NOx adsorber is fluidly connected to the exhaust stream such that NOx contained in the exhaust stream may be adsorbed by the NOx adsorber. When the NOx reactor is in an online configuration, the NOx reactor is fluidly connected to the NOx adsorber such that NOx adsorbed by the NOx adsorber may be treated by the NOx reactor.

The exhaust treatment system is preferably for NOx abatement of an exhaust stream from a process tool. The process tool may be a tool used in the manufacturing of semiconductors. For example, the exhaust treatment system may be an Atlas™ abtement system, as provided by Edwards Limited.

The exhaust stream may comprise one or more of NOx, nitrous oxides (N₂O), nitrogen trifluoride (NF₃), fluorine (F₂), and/or silane (SiH₄). The skilled person will understand that the exhaust stream may comprise further constituent components, dependent at least in part on the process from which the exhaust stream is produced.

The (or each) NOx adsorber may reversibly adsorb NOx, such that the NOx may be desorbed when the NOx reactor is online with respect to said NOx adsorber. The NOx adsorber may comprise a transitional metal, a precious metal, a noble metal, an alkaline earth metal or alkali metal. The NOx adsorber may comprise magnesium oxide (MgO), and/or hopcalite (CuMnOₓ), and/or palladium, and/or platinum, and/or copper, and/or cobalt, and/or any of the alkali metals or alkaline earth metals, such as magnesium or sodium. The NOx adsorber may optionally be dispersed on various supports, such as ceria, silica, alumina, or zeolite supports. In some embodiments, combinations of the above listed metals on a silicate, alumina, ceria or zeolitic supports containing alkali metals or alkaline metals may be used. For example, the NOx adsorber may be palladium, platinum, copper, cobalt, potassium, sodium, silver, or combinations thereof supported on ceria. In a preferred embodiment, the NOx adsorber may comprise magnesium oxide (MgO).

In embodiments, the or each NOx adsorber may be selected from the list containing magnesium oxide (MgO), barium oxide (BaO), platinum on alumina (Pt/Al₂O₃), alumina (Al₂O₃), cerium dioxide (CeO₂), platinum on cerium dioxide (Pt/CeO₂), palladium on cerium dioxide (Pd/CeO₂), palladium on tungsten oxide and zirconia (Pd/WO₃ZrO₂). The NOx adsorber may alternatively be palladium (Pd), platinum (Pt), barium oxide (BaO) or lanthanum oxide (LaO), on ceria, alumina, silica, or zeolites. The NOx adsorber may alternatively be alumina, silica, zeolites, or ceria, containing platinum (Pt), palladium (Pa), lanthanum (La), praseodymium (Pr), samarium (Sm), neodymium (Nd), and/or yttrium (Y).

The skilled person will appreciate that the system of the present invention enables selection from a broad range of materials for the NOx adsorber. Advantageously, the NOx adsorber may be cheaper to produce and to replace than the NOx reactor. The NOx adsorber may be selected according to the specific composition of the exhaust stream. In embodiments comprising a plurality of NOx adsorbers, the NOx adsorbers may be the same or may differ in composition. Preferably, the NOx adsorbers may have the same composition The at least one NOx adsorber may be arranged in fluid communication with the exhaust stream. Preferably, the exhaust stream may pass across and/or through the NOx adsorber.

The exhaust treatment system preferably comprises at least one NOx reactor, and may comprise a plurality of NOx reactors. Preferably, at least one NOx adsorber may be arranged fluidly upstream of at least one NOx reactor.

When the NOx reactor is in an offline configuration, it is fluidly disconnected from exhaust stream and the NOx adsorber. Fluidly disconnected means that substantially none of the exhaust stream passes across and/or through the NOx reactor. This fluid disconnection may be achieved using a valve or other suitable means. In some embodiments, the NOx reactor may be simultaneously fluidly disconnected with a first NOx adsorber with which it is in an offline configuration, and fluidly connected with a second NOx adsorber with which it is in an online configuration.

When the NOx reactor is in an online configuration with respect to the NOx adsorber, the NOx reactor is fluidly connected to NOx adsorber. NOx may be desorbed from the NOx adsorber, and may transfer to the NOx reactor for treatment. Treatment of the NOx by the NOx reactor may involve reduction of the NOx (i.e. decomposition). Said treatment may preferably comprise direct decomposition, or it may comprise reduction in the presence of a reducing agent. Preferably, the NOx reactor may remain fluidly disconnected from exhaust stream, even when in an online configuration. Most preferably, the NOx reactor may remain fluidly disconnected from the exhaust stream at all times to avoid degradation and/or deactivation of the NOx reactor. The outputs of the NOx decomposition may preferably be nitrogen and water.

Advantageously, exhaust treatment systems according to the present invention may address a number of problems associated with exhaust treatment systems of the prior art. The arrangement of the present exhaust treatment system may ensure that substantially no oxygen, water vapour, and/or particulates present in the exhaust stream may pass across or through the NOx reactor. This may be as a result of the NOx reactor being fluidly disconnected from the exhaust stream, and because the oxygen, water vapour and/or particulates are not adsorbed to the NOx adsorber. Accordingly, the likelihood of fouling or deactivation of the NOx reactor may be significantly reduced, and the lifespan of the NOx reactor may be increased.

Furthermore, the fluid disconnection of the NOx reactor and exhaust stream may allow for direct NOx decomposition, as the NOx reactor is not in an oxygen-rich environment. Beneficially, this may allow for the selection from a wider range of NOx reactors. This may also avoid the requirement of a reducing agent. By having greater control over the conditions of NOx decomposition, the operational lifetime of the NOx reactor may be increased, and the time between servicing may also be increased.

A further benefit of the fluid disconnection of the NOx reactor and the exhaust stream may be a reduction in the pressure drop within the system, enabling smaller particulates of NOx reactor (e.g. catalyst) to be used. This may also allow use of NOx reactor materials that would otherwise be unfeasible.

In some embodiments, the NOx reactor may be a catalyst. Preferably, the NOx reactor may be a catalyst unit comprising a catalyst and heating means operable to heat the catalyst. The catalyst may be, for example, a Cu-ZSM-5 zeolite catalyst, a cerium doped Cu-ZSM-5 zeolite catalyst, a platinum on alumina catalyst (Pt/AL₂O₃), a cobalt(II, III) oxide catalyst (CO₃O₄), a Ba(MgO) catalyst, a Na—Co₃O₄ catalyst, a La₂CuO₄ catalyst, a Fe-ZSM5, Fe-BEA, or Vanadium catalyst doped with molybdenum or Tungsten oxides. The skilled person will appreciate that the catalyst is not explicitly limited to the above examples.

Preferably, the catalyst may enable direct decomposition of the NOx.

Typically, the catalyst may be in particulate/granular form. The present invention may also facilitate the use of smaller granule sizes of catalyst. As the NOx reactor is fluidly disconnected from the exhaust stream, the greater pressure drop associated with the smaller granule size of the catalyst may not affect the overall pressure drop of the system. In systems of the present invention, the pressure drop of the exhaust stream may be primarily affected by the NOx adsorber, rather than the NOx reactor.

In an alternative embodiment, the NOx reactor may be a catalyst, and the catalyst chamber may be supplied with a reducing agent when the NOx adsorber is in an offline configuration. By way of example, the reducing agent may comprise carbon monoxide (CO), hydrogen (H₂), methane (CH₄), propane (C₃H₈), or ammonia (NH₃).

The reducing agent selected may depend on the NOx reactor that is present. For example, a methane (CH₄) reducing agent may be used with Pt/CeZrO₂ catalysts, Co-ZSM-5 catalysts, Co-BEA zeolite catalysts, or Co-Mordenite catalysts. A propane (C₃H₈) reducing agent may be used with Fe-ZSM-5 catalysts, or Fe-BEA zeolite catalysts. A carbon monoxide (CO) reducing agent may be used with Pt/Al₂O₃ catalysts, or Pt/CeO₂ catalysts.

In alternative embodiments, the NOx reactor may comprise a plasma reactor. Plasma reactor may generate plasma typically using electrical discharge or by electron-beam. In either case, the result is to split the constituents of air into smaller energetic gaseous mixtures of ions and electrons. By way of example, the plasma reactor may comprise a di-electric barrier discharge (DBD) plasma reactor, a radio frequency plasma generator, and/or a microwave frequency plasma generator. The plasma may be generated by an electron-beam or electrical discharge method. Optionally, during operation the plasma reactor may be heated. Advantageously, this may improve NOx reaction in the plasma reactor.

In alternative embodiments, the NOx reactor may comprise a plasma-assisted catalyst. The NOx reactor may comprise both a catalyst and a plasma reactor. The catalyst may be as described hereinbefore. The plasma chamber may be as defined hereinbefore. Preferably, the plasma chamber may be fluidly upstream of the catalyst. Advantageously, the combination of a catalyst and a plasma reactor may enhance the reaction of NOx.

The skilled person will appreciate that further features described in relation to the exhaust treatment system may be used with any embodiment of the NOx reactor. For example, embodiments may include those wherein a NOx reactor is a catalyst, a reducing agent assisted catalyst, a plasma chamber, and/or a plasma-assisted catalyst.

Typically, the exhaust treatment system may comprise a plurality of NOx adsorbers. During operation of the exhaust treatment system, the NOx reactor may be in an online configuration with respect to at least one NOx adsorber, and in an offline configuration with respect to at least one NOx adsorber. Preferably, during operation of the exhaust treatment system, the NOx reactor may simultaneously be in an online configuration with respect to at least one NOx adsorber, and in an offline configuration with respect to at least one NOx adsorber. The exhaust treatment system may comprise from about 2 to about 4 NOx adsorbers, preferably 2 NOx adsorbers.

In a particularly preferred embodiment, the exhaust treatment system may comprise a NOx reactor and two NOx adsorbers, wherein during operation of the exhaust treatment system, the NOx reactor may be in an online configuration with respect to one NOx adsorber and in an offline configuration the other NOx adsorber. The NOx reactor may be switchable between an online configuration and an offline configuration with respect to each NOx adsorber.

The exhaust treatment system may comprise a plurality of NOx reactors and a plurality of NOx adsorbers. In such embodiments, during operation of the exhaust treatment system, at least one NOx reactor may be in an online configuration with respect to at least one NOx adsorber, and at least one NOx reactor may be in an offline configuration with at least one NOx adsorber. The plurality of NOx reactors may be the same, or the NOx reactors may be of different types.

Ensuring that during operation of the exhaust treatment system the (or a) NOx reactor is in an offline configuration with respect to at least one NOx adsorber, may advantageously allow for substantially continuous adsorption of NOx from the exhaust stream via said at least one NOx adsorber. Furthermore, NOx adsorbed to the NOx adsorber with which the NOx reactor is in an online configuration can be treated simultaneously.

The arrangement of the present invention is also beneficial as it may accommodate fluctuations in the NOx concentration of the exhaust stream. NOx adsorbers can be highly effective at removing NOx from exhaust streams, even when the flow rate of the exhaust stream across/through the NOx adsorber is relatively high. The present invention allows for the NOx adsorber with which the NOx reactor is in an offline configuration to adsorb NOx from the exhaust stream, whilst NOx released from the NOx adsorber with which the NOx reactor is in an online configuration is being treated.

The present invention may be particularly advantageous for applications wherein the NOx concentration of the exhaust stream is relatively high for a short duration, followed by a longer duration when the NOx concentration is relatively low. At least one NOx adsorber can be fluidly connected to the exhaust stream during the short duration wherein the NOx concentration is relatively high, then the NOx reactor can be switched to be online with respect to this NOx adsorber during the period wherein the NOx concentration is relatively low. The present invention may thereby allow more time for the NOx reactor to decompose the NOx present during the elevated NOx concentration of the exhaust stream, compared with if the NOx reactor were in continuous fluid connection with the exhaust stream. The present invention increases the time allotted for NOx decomposition, such that it is more proportional to the amount of NOx that must be treated. This may advantageously improve NOx reduction.

The separation of the NOx reactor from the exhaust stream in the present invention may allow for the controlled release of NOx from the NOx adsorber with which the NOx reactor is in an online configuration. This may enable the effects of fluctuations in the NOx concentration of the exhaust stream on the NOx reaction rate to be reduced, as NOx can be released from the NOx adsorber at a substantially continuous rate. Having greater control over the release rate of NOx for treatment by the NOx reactor is beneficial, as this enables greater control over the reaction conditions at the NOx reactor, such that it is not required to be as versatile. Additionally, this may be beneficial when the NOx reactor comprises a catalyst, because controlling the release rate of NOx may enable the volume of catalyst to be reduced. Catalysts, particularly direct NOx catalysts, are often expensive to produce so a reduction in the amount of catalyst required is beneficial. Furthermore, catalysts may require elevated temperatures to decompose NOx effectively. Reducing the volume of catalyst may decrease the overall energy requirements of the system, whilst still allowing substantially continuous abatement of NOx.

The present invention may also provide the ability to preconcentrate NOx prior to decomposition by the NOx reactor, by controlling the release rate of NOx from the NOx adsorber. For certain NOx reactors, the preconcentration of NOx may be beneficial as the rate of NOx conversion (i.e. NOx decomposition) may be concentration dependant. For example, in embodiments wherein the NOx reactor is a Cu-ZSM5 direct NOx catalyst, preconcentration of NOx at the NOx adsorber prior to release may provide improved NOx decomposition.

Typically, during operation of the exhaust treatment system, the or a NOx reactor may be switchable between an online configuration and an offline configuration with respect to at least two NOx adsorbers. Advantageously, this may aid in allowing the substantially continuous abatement of NOx from an exhaust stream.

In embodiments comprising more than one NOx reactor and more than one NOx adsorber, at least one NOx reactor-NOx adsorber pair may switch to an online configuration when another NOx reactor-NOx adsorber pair switches to an offline configuration.

Preferably, the exhaust treatment system may further comprise a controller. The controller may be configured to switch the or a NOx reactor between an offline configuration and an online configuration with respect to the or each NOx adsorber in response to an input signal. Preferably, the input signal may be from a process tool to which the exhaust treatment system is connected. Additionally, or alternatively, the input signal may be from a sensor measuring the exhaust stream. The sensor may measure the NOx concentration of the exhaust stream. Additionally, or alternatively, the sensor may measure other parameters indicative of NOx release.

Additionally, or alternatively, the exhaust treatment system may further comprise at least one temperature sensor configured to measure the temperature of the NOx reactor. In such embodiments, the input signal may be from the temperature sensor connected to the NOx reactor. Additionally, or alternatively, the input signal may be from a timer.

Preferably, the controller may be configured to automatically switch the NOx reactor between an offline configuration and an online configuration with respect to at least a pair of NOx adsorbers in response to an input signal passing a threshold value. For the avoidance of doubt, the input signals may be as set out hereinbefore. Advantageously, this may allow substantially automatic operation of the exhaust treatment system and enable substantially continuous NOx abatement of the exhaust stream.

The monitoring of the NOx reactor and/or NOx adsorber(s) may provide information on the activity of the NOx reactor and/or NOx adsorber(s). This may aid in ensuring that the system is adequately abating NOx from the exhaust stream, and may notify the user as to when the catalyst and/or NOx adsorber(s) require maintenance and/or replacement.

Typically, the NOx reactor may be located within a reactor chamber. For example, when the NOx reactor is a catalyst, the catalyst may be located within a catalyst chamber. Preferably, the catalyst chamber can withstand pressures of up to about 50 bar. The catalyst chamber may therefore be pressurised during operation.

Typically, the exhaust treatment system may further comprise heating means operable to heat the NOx adsorber when the NOx reactor is in an online configuration therewith. Preferably, the heating means may comprise a heating element, a flame (i.e. hot gas), an electrical induction heater, and/or a microwave induction heater. The heating means may be operable via the controller, and this operation may be automated. Heating the NOx adsorber with which the NOx reactor is in an online configuration may increase the rate of desorption (i.e. release) of NOx from the NOx adsorber. The temperature to which the NOx adsorber is heated may provide control over the release rate of NOx from the NOx adsorber.

Typically, when in fluid communication with the exhaust stream (i.e. when the NOx reactor is offline with respect to the NOx adsorber), the NOx adsorber may be heated by the heating means to a temperature of at least 100° C. This may reduce the likelihood of water vapour within the exhaust stream forming hydroxides. Water may also cause physical pore blocking of the NOx adsorber, thereby reducing or preventing NOx adsorption.

Typically, when the NOx reactor is online with respect to the NOx adsorber, the adsorber may be heated by the heating means to temperatures greater than about 100° C., preferably greater than about 200° C., for example greater than about 600° C. Advantageously, this may aid in the decomposition of NOx. Alternatively, the temperature of the NOx reactor may remain substantially constant and NOx left to evolve naturally at the temperature at which it adsorbed.

Typically, the exhaust treatment system may further comprise a substantially inert gas flow operable to transfer NOx released by the NOx adsorber to the NOx reactor. The substantially inert gas flow may comprise nitrogen, ‘dry’ air with controlled oxygen concentration, argon, and/or carbon dioxide. Preferably, the substantially inert gas flow comprises nitrogen. The substantially inert gas flow may aid in the transfer of NOx from the NOx adsorber to the NOx reactor when the NOx reactor is in an online configuration with respect to the NOx adsorber. The flow rate of the substantially inert gas flow may determine the amount of NOx treated at the NOx reactor. The flow rate of the substantially inert gas flow may be controlled, preferably via the controller.

Preferably, the flow rate of the substantially inert gas flow and the temperature control provided by the heating means may operate in concert to control the release of NOx from the NOx adsorber and the flow rate of NOx across the NOx reactor.

The substantially inert gas flow may comprise further additives. For example, a reducing agent may be added to the substantially inert gas flow. The reducing agent may comprise carbon monoxide, hydrogen, ammonia, methane, propane, and/or propene. Such additives may be appropriate when the NOx reactor is a catalyst that is particularly susceptible to deactivation by water vapour. For example, Co-ZSM-5 catalysts or Co-Ferrierite catalysts are highly sensitive to water vapour within the exhaust gas flow, which can lead to deactivation of the catalyst. Accordingly, in such instances, the inclusion of such additives in the substantially inert gas flow may be beneficial. Beneficially, the reducing agent may assist desorption of NOx from the NOx adsorber. Providing net reducing conditions at the NOx adsorber may enable the NOx adsorber to desorb NOx at a lower temperature. This may reduce the running costs of the system.

Typically, the exhaust treatment system may comprise a foraminous burner, electrical induction heater, or plasma reactor. The foraminous burner, electrical induction heater, or plasma reactor may be arranged upstream of the NOx adsorber(s). This may enable pre-heating of the exhaust gas stream.

Typically, the exhaust treatment system may further comprise an acid gas scrubber. The acid gas scrubber may be arranged upstream of the NOx adsorber(s). Advantageously, this may enable removal of acid gases from the exhaust gas stream prior to passing over/through the NOx adsorber(s) and NOx reactor(s).

In another aspect, the present invention provides a method for abating NOx from an exhaust stream. The method comprises the steps of:
i) Providing an exhaust treatment system according to any preceding aspect or embodiment.
ii) Directing the exhaust stream from the process tool across an NOx adsorber with which the NOx reactor is in an offline configuration.
iii) Adsorbing NOx from the exhaust stream onto the NOx adsorber.
iv) Switching the NOx reactor from an offline configuration to an online configuration with respect to the NOx adsorber.
v) Releasing NOx from the NOx adsorber and directing said released NOx to the NOx reactor for treatment.

For the avoidance of doubt, the NOx adsorber and NOx reactor may be as described in relation to the preceding aspect.

Preferably, the NOx released during step (v) is substantially free from O₂, and/or H₂O, and/or particulates present in the exhaust stream. “Substantially free” may be defined as less than about 1 vol. %, preferably less than about 0.1 vol. %.

Advantageously, this method may significantly reduce the risk of fouling or deactivation of the NOx reactor, as the NOx reactor is not in fluid communication with the exhaust stream. Accordingly, direct NOx decomposition may be possible, allowing selection from a wider range of NOx reactors and the avoidance of the requirement of a reducing agent. The operational lifetime of the NOx reactor may be increased, and the time between servicing may be reduced.

Preferably, in step (iii), following adsorption of NOx onto the NOx adsorber, the exhaust stream may be directed towards an outlet of the exhaust treatment apparatus, and may be conveyed to the outlet via further abatement apparatus.

Preferably, step (iv) further comprises directing the exhaust stream from the process tool across a further NOx adsorber with which the NOx reactor is in an offline configuration. Advantageously, this may allow for substantially continuous adsorption and treatment of NOx from the exhaust stream. This may also accommodate fluctuations in the NOx concentration of the exhaust stream. The present method may allow the NOx adsorber with which the NOx reactor is in an offline configuration to adsorb NOx from the exhaust stream, whilst NOx released from the NOx adsorber with which the NOx reactor is in an online configuration is being treated. This may provide more time for the NOx reactor to decompose the NOx present during a peak in NOx concentration of the exhaust stream than if the NOx reactor were in permanent fluid communication with the exhaust stream.

Preferably, step (v) involves heating the NOx adsorber to a temperature greater than about 100° C., preferably greater than about 200° C., for example greater than about 600° C. Advantageously, this may aid in desorption of NOx from the NOx adsorber, allowing transfer of desorbed NOx to the NOx reactor for treatment.

Preferably, step (v) further comprises introducing a substantially inert gas flow to transfer the released NOx to the NOx reactor. Preferably, the substantially inert gas flow may comprise nitrogen, argon, ‘dry’ air with a controlled oxygen concentration, and/or carbon dioxide. Preferably, the substantially inert gas flow comprises nitrogen. The substantially inert gas flow may comprise further additives. For example, carbon monoxide, ammonia, hydrogen, methane, propane, and/or propene may be added to the substantially inert gas flow as reducing agents. Advantageously, the substantially inert gas flow may aid in the control of the transfer of NOx from the NOx adsorber to the NOx reactor, as described hereinbefore.

Preferably, the flow rate of the substantially inert gas flow may be selectively modulated to control the delivery rate of NOx to the NOx reactor. Having control over the release rate of NOx for treatment by the NOx reactor may be beneficial as the effects of fluctuations in the NOx concentration of the exhaust stream on the NOx reaction rate may be reduced. This may be particularly advantageous when the NOx reactor comprises a catalyst, as volume of catalyst required can be reduced. The catalyst is often expensive to produce, and may require elevated temperatures to decompose NOx effectively. Reducing the volume of catalyst that must be maintained at elevated temperatures may make the operation of the exhaust treatment system more cost-effective, whilst still allowing for substantially continuous abatement of NOx.

Preferably, the method may further comprise the step of modulating the pressure within the NOx reactor chamber during step (v) to increase and/or decrease the rate of decomposition of the released NOx by the NOx reactor. Increasing the pressure may increase the rate of decomposition of the released NOx by the NOx reactor, and decreasing the pressure may decrease the rate of decomposition of the released NOx by the NOx reactor.

Preferably, the method may be substantially automated by a controller. Particularly, step (iv) may be initiated by a signal output by the process tool to which the exhaust treatment system is connected, and/or by a sensor measuring the NOx concentration of the exhaust stream, and/or by a sensor measuring the temperature of the NOx reactor, and/or by a timer.

Preferably, the modulation of the temperature of the NOx adsorber and/or the flow rate of the substantially inert gas flow of step (v) may be automated and controlled by the controller.

Preferably, the modulation of the pressure of the NOx reactor may be automated and controlled by the controller.

In another aspect, the present invention provides the use of magnesium oxide, an alkaline earth material, an alkali metal, a transitional metal, a precious metal, a noble metal, palladium, platinum, copper, cobalt, and/or Hopcalite, to adsorb NOx from an abatement gas stream and subsequently desorb said NOx for catalytic treatment. Optionally, supports such as zeolites may be used also containing such metals copper, cobalt, silver, platinum or palladium. Preferably, the magnesium oxide and/or Hopcalite, or palladium/platinum on silicate supports, or silver, copper and cobalt-based transition metal oxides, or combinations thereof, is fluidly disconnected from the means for catalytic treatment when adsorbing NOx from the abatement gas stream. The advantages of this aspect are as described in the preceding aspects and embodiments.

For the avoidance of doubt, all aspects and embodiments described hereinbefore may be combined mutatis mutandis.

The Summary is provided to introduce a selection of concepts in a simplified form that are further described in the Detailed Description. This summary is not intended to identify key features or essential features of the claimed subject matter, nor is it intended to be used as an aid in determining the scope of the claimed subject matter.

### BRIEF DESCRIPTION OF THE DRAWINGS

Preferred features of the present invention will now be described, by way of example, with reference to the accompanying drawings, in which:

FIG. 1 shows a schematic of an exhaust treatment system (1) in accordance with the prior art;

FIGS. 2A-B show schematic views of an embodiment of an exhaust treatment system in accordance with the present invention;

FIGS. 3A-B show a schematic views of an alternative embodiment of an exhaust treatment system in accordance with the present invention;

FIG. 4 shows a flow chart of a method in accordance with the present invention.

### DETAILED DESCRIPTION

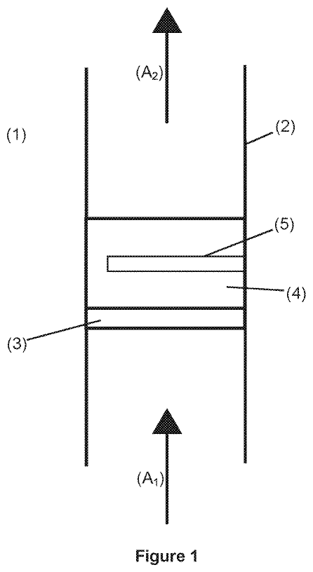

FIG. 1 illustrates a schematic of an exhaust treatment system (1) in accordance with the prior art. The system (1) comprises a conduit (2) through which the exhaust stream travels. The direction of flow of the exhaust stream through the exhaust treatment system (1) is shown by arrows A1 and A2. Arrow A1 shows the direction of flow of the exhaust stream from the process tool into the exhaust treatment system (1), and arrow A2 shows the direction of flow of the exhaust stream following abatement.

The exhaust treatment system (1) comprises a NOx adsorber (3) attached to a catalyst (4). The NOx adsorber (3) and catalyst (4) are arranged in series within the conduit (2), and are both in fluid communication with the exhaust stream throughout operation of the exhaust treatment system (1). The catalyst (4) contains a heating element (5) embedded within, to maintain the catalyst (4) at elevated temperatures during operation. In use, the temperature of the heating element (5) may be adjusted to improve NOx adsorption and desorption conditions.

The arrangement of the exhaust treatment system (1) of the prior art presents a number of issues. A reducing agent (not shown) may be required to aid in the decomposition of NOx by the catalyst (4). The presence of oxygen in the exhaust stream when such reducing agents are used is undesirable, as the reaction of O₂ with CO consumes much of the CO required to facilitate the reaction between CO and NO. This may reduce the efficiency of NOx decomposition. Water vapour present within the exhaust stream can cause deactivation of the catalyst (4). Particulate matter, such as silica, present in the exhaust stream may foul the catalyst (4) and thereby reduce its activity.

Additionally, the concentration of NOx within the exhaust stream may vary. As the catalyst (4) is in fluid communication with the exhaust stream, the catalyst (4) must be able to meet the abatement requirements during the peak NOx concentration.

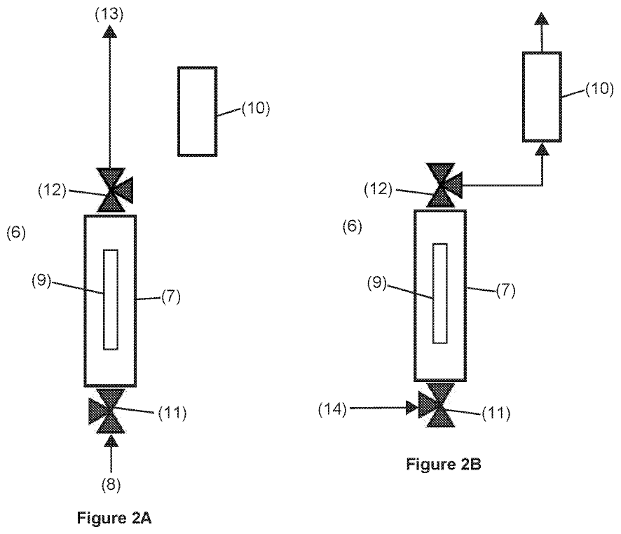

FIGS. 2A-B illustrate schematic views of an embodiment of an exhaust treatment system (6) in accordance with the present invention. The exhaust treatment system (6) comprises an NOx adsorber (7) configured to adsorb NOx from an incoming exhaust stream (8). The NOx adsorber (7) is a passive NOx adsorber, comprising, for example, magnesium oxide (MgO). A heating element (9) is embedded within the NOx adsorber (7).

The exhaust treatment system (6) further comprises a NOx reactor (10). The NOx reactor (10) comprises a catalyst, a reducing agent-assisted catalyst, a plasma reactor, or a plasma-assisted catalyst, as described hereinbefore. For example, the NOx reactor (10) may be a Cu-ZSM-5 zeolite catalyst. A first valve (11) is arranged upstream of the NOx adsorber (7). A second valve (12) is arranged downstream of the NOx adsorber (7).

FIG. 2A shows the arrangement of the exhaust treatment system (6) when the NOx reactor (10) is in an offline configuration. In such a configuration, the NOx reactor (10) is fluidly disconnected from the exhaust stream (8) and from the NOx adsorber (7). In the embodiment shown, this fluid disconnection of the NOx reactor (10) from the exhaust stream (8) and from the NOx adsorber (7) is provided by the downstream valve (11). The exhaust stream (8) enters the exhaust treatment system (6) from a process tool (not shown) via the first valve (11), and is conveyed across the NOx adsorber (7). NOx is adsorbed onto the NOx adsorber (7), and thereby is removed from the exhaust stream (8). The treated exhaust stream (13) then travels through the downstream valve (12) and exits the exhaust treatment system (6).

The temperature of the NOx adsorber (7) is typically at least about 100° C. when the NOx reactor (10) is in an offline configuration. This is because NOx is readily adsorbed by the NOx adsorber (7) from the exhaust stream (8) at these temperatures.

The NOx reactor (10) is not exposed to the exhaust stream (8) at all when in the offline configuration, as the NOx reactor (10) is fluidly disconnected from the exhaust stream (8). Accordingly, no oxygen, water vapour, and/or particulates that might be present in the exhaust stream (8) pass across or through the NOx reactor (10). Beneficially, this may avoid deactivation and/or fouling of the NOx reactor (10), particularly wherein the NOx reactor is a catalyst.

FIG. 2B shows the arrangement of the exhaust treatment system (6) when the NOx reactor (10) is in an online configuration. In such a configuration, the NOx reactor (10) is fluidly connected to the NOx adsorber (7), via the second valve (12). The exhaust stream (8) is no longer entering the exhaust treatment system (6), via the first valve (11). Therefore, the NOx reactor (10) is fluidly disconnected from the exhaust stream (8), even when in an online configuration with the NOx adsorber (7) The heating element (9) is operated to increase the temperature of the NOx adsorber (7) to a temperature greater than about 200° C., preferably greater than about 300° C., for example greater than about 600° C. This increase in temperature of the NOx adsorber (7) facilitates the release of NOx adsorbed thereto. A substantially inert gas flow (14) is activated. Preferably, the substantially inert gas flow (14) comprises nitrogen. The substantially inert gas flow (14) is directed across/through the NOx adsorber (7) via the first valve (11). The substantially inert gas flow (14) transfers the NOx released by the NOx adsorber (7) to the NOx reactor (10) via the second valve (12). The NOx reactor (10) treats the NOx carried by the nitrogen gas flow (14).

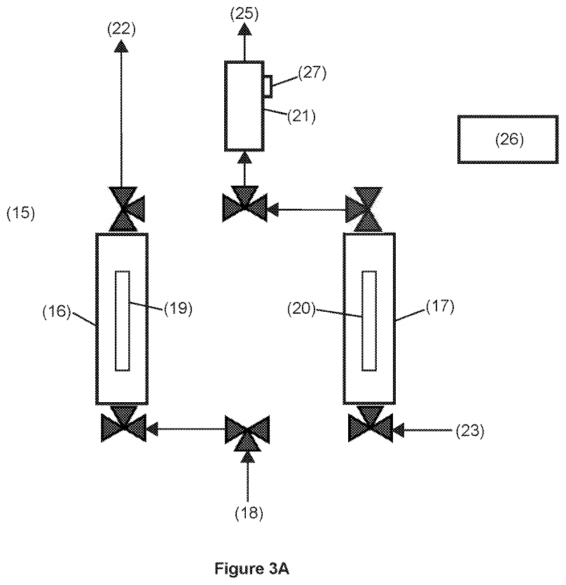

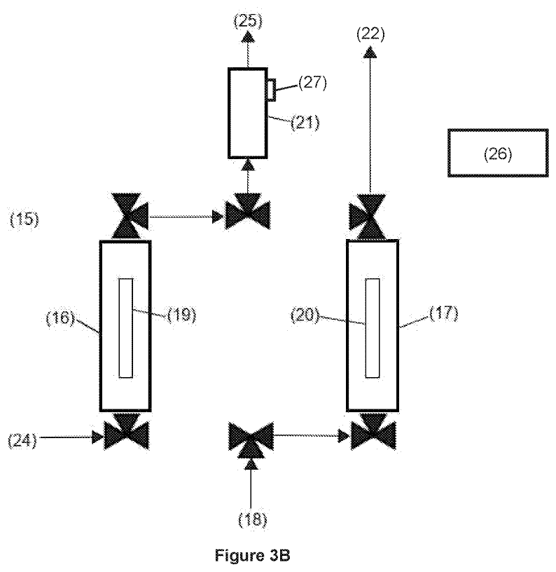

FIGS. 3A-B illustrate schematic views of an alternative embodiment of an exhaust treatment system (15) in accordance with the present invention. The exhaust treatment system (15) comprises a first NOx adsorber (16) and a second NOx adsorber (17), each configured to adsorb NOx from an incoming exhaust stream (18). The first and second NOx adsorbers (16,17) are passive NOx adsorbers comprising magnesium oxide (MgO). A heating element (19,20) is present within each NOx adsorber (16,17), and configured to regulate the temperature thereof.

The exhaust treatment system (15) further comprises a NOx reactor (21). The NOx reactor (21) comprises a catalyst, a reducing agent-assisted catalyst, a plasma reactor, or a plasma-assisted catalyst, as described hereinbefore. For example, the NOx reactor (21) may be a Cu-ZSM-5 zeolite catalyst. A series of valves are present and configured to fluidly connect and disconnect portions of the exhaust treatment system (15).

FIG. 3A illustrates when the NOx reactor (21) is in an offline configuration with respect to the first NOx adsorber (16), and in an online configuration with respect to the second NOx adsorber (17). Accordingly, the NOx reactor (21) is fluidly disconnected from the exhaust stream (18) and from the first NOx adsorber (16). The exhaust stream (18) enters the exhaust treatment system (15) from a process tool (not shown) and is conveyed across the first NOx adsorber (16).

The temperature of the first NOx adsorber (16) is typically at least about 100° C. in this configuration. NOx is adsorbed onto the first NOx adsorber (16), and thereby is removed from the exhaust stream (18). The treated exhaust stream (22) then exits the exhaust treatment system (15) without passing across/through the NOx reactor (21).

The NOx reactor (21) is not exposed to the exhaust stream (18) at all, when in an offline or online configuration with respect to either NOx adsorber (16,17). Accordingly, no oxygen, water vapour, and/or particulates that might be present in the exhaust stream (18) pass across/through the NOx reactor (21). Beneficially, this may avoid deactivation or fouling of the NOx reactor (21).

Simultaneously, the NOx reactor (21) is in an online configuration with respect to the second NOx adsorber (17). The NOx reactor (21) is fluidly connected to the second NOx adsorber (17), via a valve. The second heating element (20) is operated to increase the temperature of the second NOx adsorber (17). Preferably the temperature of the second NOx adsorber (17) may be increased to greater than about 200° C., preferably greater than about 300° C., for example about 600° C. This increase in temperature of the NOx adsorber (17) releases NOx adsorbed thereto from a previous cycle when the NOx reactor (21) was in an offline configuration with respect to the second NOx adsorber (17).

A substantially inert gas flow (23), preferably comprising nitrogen, is directed across/through the second NOx adsorber (17) to transfer the NOx released by the second NOx adsorber (17) to the NOx reactor (21). The NOx reactor (21) treats the NOx carried by the substantially inert gas flow (23), which then exits the exhaust treatment system (15) via an outlet (25).

FIG. 3B illustrates when the NOx reactor (21) is in an online configuration with respect to the first NOx adsorber (16), and in an offline configuration with respect to the second NOx adsorber (17). Accordingly, the NOx reactor (21) is fluidly disconnected from the exhaust stream (18) and from the second NOx adsorber (17). The exhaust stream (18) enters the exhaust treatment system (15) from a process tool (not shown) and is conveyed across the second NOx adsorber (17).

The temperature of the second NOx adsorber (17) is typically at least about 100° C. in this configuration. NOx is adsorbed onto the second NOx adsorber (17), and thereby is removed from the exhaust stream (18). The treated exhaust stream (22) then exits the exhaust treatment system (15) without passing through the NOx reactor (21).

Simultaneously, the NOx reactor (21) is in an online configuration with respect to the first NOx adsorber (16). The NOx reactor (21) is fluidly connected to the first NOx adsorber (16), via a valve. The first heating element (19) is operated to increase the temperature of the first NOx adsorber (16) to a temperature greater than about 200° C., preferably greater than about 300° C., for example about 600° C. This increase in temperature of the first NOx adsorber (16) releases NOx adsorbed thereto when in the configuration illustrated in FIG. 3A.

A substantially inert gas flow (24), preferably comprising nitrogen, is directed across/through the first NOx adsorber (16) to transfer the NOx released by the first NOx adsorber (16) to the NOx reactor (21). The NOx reactor (21) treats the NOx carried by the substantially inert gas flow (24), which then exits the exhaust treatment system (15) via an outlet (25).

During operation of the exhaust treatment system (15), the system (15) switches between the configuration of FIG. 3A and that of FIG. 3B. Accordingly, the NOx reactor (21) is always in an online configuration with respect to one NOx adsorber (16,17), and in an offline configuration with respect to the other NOx adsorber (16,17). Advantageously, this may allow substantially continuous NOx removal from the exhaust stream (18), without deactivation and/or fouling of the NOx reactor (21) due to exposure to oxygen, water vapour, and/or particulates present in the exhaust stream (18).

The exhaust treatment system (15) further comprises a controller (26), configured to switch the catalyst (21) between an online configuration and an offline configuration with respect to the two NOx adsorbers (16,17). This switching may be automatic and triggered in response to an input.

The exhaust treatment system (15) may further comprise a sensor (not shown) configured to measure the NOx concentration of the incoming exhaust stream (18). The sensor may output a signal to the controller (26), which can trigger the switch of the configuration of the NOx reactor (21), for example when the NOx concentration of the exhaust stream (18) passes a threshold value.

The exhaust treatment system may further comprise a temperature sensor (27) configured to measure the temperature of the NOx reactor (21). The temperature sensor (27) may output a signal to the controller (26), which can trigger the switch of the configuration of the NOx reactor (21), for example when the temperature of the NOx reactor (21) passes a threshold value.

The NOx reactor (21) is located within a chamber (not shown), which may be pressurised to increase and decrease the reaction rate of the NOx at the NOx reactor (21). The pressure of the chamber may be controller by the controller (26), and is preferably automated. The flow rate of the substantially inert gas flow (23,24) may be varied via the controller, preferably this may be automated. The pressure of the chamber and/or flow rate of the substantially inert gas flow (23,24) may be selected according to the concentration of NOx of the incoming exhaust stream (18).

The exhaust treatment system (15) may further comprise heating means (not shown) arranged upstream of the NOx adsorbers (16,17). The heating means may be configured to heat the exhaust gas stream (18). The heating means may comprise, for example, a foraminous burner, an electrical induction heater, or a plasma reactor.

The exhaust treatment system (15) may further comprise an acid gas scrubber (not shown). The acid gas scrubber may be arranged upstream of the NOx adsorbers (16,17). The acid gas scrubber may be configured to remove acid gases from the exhaust gas stream (18).

The exhaust treatment system (15) is preferably connected to a process tool from a semiconductor manufacturing process during operation.

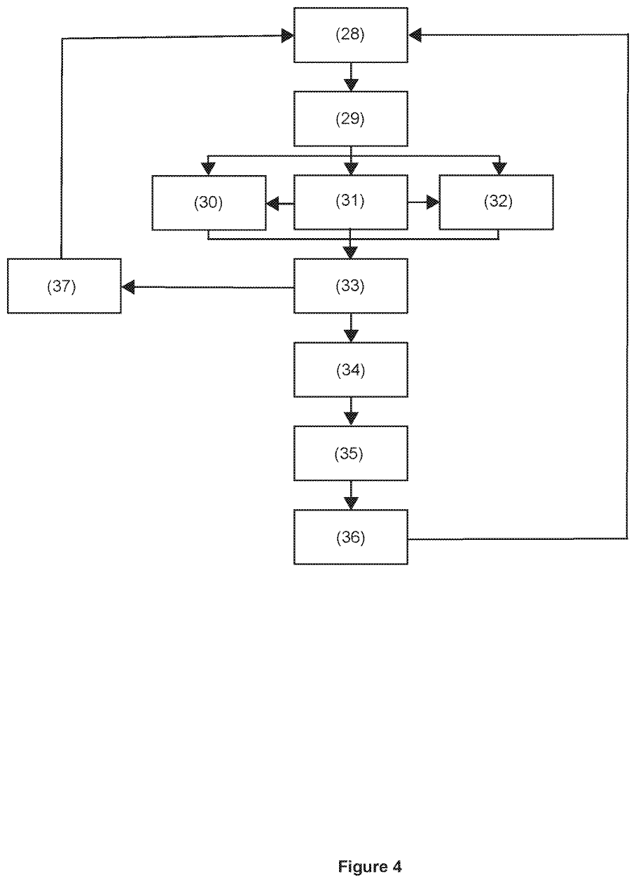

FIG. 4 illustrates a flow chart of a method in accordance with the present invention.

An exhaust treatment system according to FIG. 2A-B or 3A-B is provided. An exhaust stream is directed from the process tool across and/or through an NOx adsorber with which the NOx reactor is in an offline configuration (28). NOx present in the exhaust stream is adsorbed onto the NOx adsorber with which the NOx reactor is in an offline configuration (29).

The NOx concentration of the exhaust stream may be measured by a sensor, and this measurement may be output to the controller (30). The sensor may measure the NOx concentration of the exhaust stream at predetermined time intervals, or the sensor may measure the NOx concentration of the exhaust stream substantially continuously.

Additionally, or alternatively, the temperature of the NOx reactor may be measured via a temperature sensor, and this measurement may be output to the controller (31). The temperature sensor may measure the temperature of the NOx reactor at predetermined time intervals, or the temperature sensor may measure the temperature of the NOx reactor substantially continuously.

Additionally, or alternatively, the process tool to which the exhaust treatment system is connected may output a signal indicating the NOx concentration of the exhaust stream (32). This signal may be output at predetermined time intervals, or the signal may be output substantially continuously.

In response to a signal (30,31,32), the controller may switch the NOx reactor from an offline configuration to an online configuration with respect to the/a NOx adsorber (33).

The/a NOx adsorber is heated to a temperature greater than about 100° C., preferably greater than about 200° C., for example to about 600° C. (34). A substantially inert gas flow, preferably comprising nitrogen, may be introduced to the NOx adsorber to transfer the released NOx to the NOx reactor for treatment (35). The released NO is substantially free from oxygen, and/or water vapour, and/or particulates that were present in the exhaust stream.

The pressure within the NOx reactor chamber may be modulated to increase and/or decrease the rate of reaction of the released NOx at the NOx reactor (36).

At step (33), the controller may switch a NOx reactor from an online configuration to an offline configuration with respect to another NOx adsorber, which will then proceed through steps (28-32).

For the avoidance of doubt, features of any aspects or embodiments recited herein may be combined mutatis mutandis. It will be appreciated that various modifications may be made to the embodiments shown without departing from the spirit and scope of the invention as defined by the accompanying claims as interpreted under patent law.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. An exhaust treatment system for NOx abatement of an exhaust stream, the exhaust treatment system comprising:
at least one NOx adsorber configured to adsorb NOx from the exhaust stream, and a NOx reactor operable in an offline configuration and an online configuration;
wherein when the NOx reactor is in an offline configuration, the NOx reactor is fluidly disconnected from the exhaust stream and the NOx adsorber, and the NOx adsorber is fluidly connected to the exhaust stream such that NOx contained in the exhaust stream may be adsorbed by the NOx adsorber; and
when the NOx reactor is in an online configuration, the NOx reactor is fluidly connected to the NOx adsorber such that NOx adsorbed by the NOx adsorber may be treated by the NOx reactor.

2. The exhaust treatment system according to claim 1, comprising a plurality of NOx adsorbers, wherein during operation of the exhaust treatment system the NOx reactor is in an online configuration with respect to at least one NOx adsorber and is in an offline configuration with respect to at least one NOx adsorber.

3. The exhaust treatment system according to claim 2, wherein during operation of the exhaust treatment system, the NOx reactor is switchable between an online configuration and an offline configuration with respect to at least two NOx adsorbers.

4. The exhaust treatment system according to claim 3, further comprising a controller configured to switch the NOx reactor between an offline configuration and an online configuration with respect to at least two NOx adsorbers in response to an input signal, preferably wherein the input signal is from a process tool to which the exhaust treatment system is connected, and/or a sensor measuring the exhaust stream, and/or a temperature sensor connected to the NOx reactor, and/or a timer.

5. The exhaust treatment system according to claim 1, wherein the NOx reactor is located in a NOx reactor chamber, preferably wherein the NOx reactor chamber can withstand pressures of up to about 50 bar.

6. The exhaust treatment system according to claim 1, further comprising heating means operable to heat the NOx adsorber when the NOx reactor is in an online configuration therewith, and/or an inert gas flow operable to transfer NOx released by the NOx adsorber to the NOx reactor.

7. The exhaust treatment system according to claim 1, wherein the NOx reactor comprises a catalyst; preferably wherein the catalyst comprises a Cu-ZSM-5 zeolite catalyst, a cerium doped Cu-ZSM-5 zeolite catalyst, a platinum on alumina catalyst, a cobalt (II, III) oxide catalyst, a Ba(MgO) catalyst, a Na-Co₃O₄ catalyst, or a La₂CuO₄ catalyst.

8. The exhaust treatment system according to claim 1, wherein the NOx reactor comprises a plasma reactor; preferably wherein the plasma reactor comprises a di-electric barrier discharge plasma reactor, a radio frequency plasma generator, or a microwave frequency plasma generator.

9. The exhaust treatment system according to claim 1, wherein at least one NOx adsorber comprises an alkaline earth material, an alkali metal, a transitional metal, a precious metal, a noble metal, palladium, platinum, copper, cobalt and/or Hopcalite, preferably wherein at least one NOx adsorber comprises MgO.

10. A method for abating NOx from an exhaust stream, comprising the steps of:
i) providing an exhaust treatment system according to claim 1;
ii) directing the exhaust stream from the process tool across an NOx adsorber with which the NOx reactor is in an offline configuration;
iii) adsorbing NOx from the exhaust stream onto the NOx adsorber ;
iv) switching the NOx reactor from an offline configuration to an online configuration with respect to the NOx adsorber;
v) releasing NOx from the NOx adsorber and transferring said released NOx to the NOx reactor for treatment.

11. The method according to claim 10, wherein the NOx released during step (v) is substantially free from O₂, and/or H₂O, and/or particulates present in the exhaust stream.

12. The method according to claim 10, wherein step (iv) further comprises directing the exhaust stream from the process tool across a further NOx adsorber with which the NOx reactor is in an offline configuration.

13. The method according to claim 10, wherein step (v) involves heating the NOx adsorber to a temperature greater than about 100° C., preferably greater than about 200° C., for example greater than about 600° C..

14. The method according to claim 10, wherein step (v) further comprises introducing a substantially inert gas flow to transfer the released NOx to the NOx reactor, preferably wherein the substantially inert gas flow comprises nitrogen, argon, and/or carbon dioxide.

15. The method according to claim 10, further comprising the step of modulating the pressure within the NOx reactor chamber during step (v) to increase and/or decrease the rate of reaction of the released NOx with the NOx reactor.

16. The method according to claim 10, wherein the method is substantially automated, and wherein step (iv) is initiated by a signal output by the process tool to which the exhaust treatment system is connected, and/or by a sensor measuring the NOx concentration of the exhaust stream, and/or by a sensor measuring the temperature of the NOx reactor, and/or by a timer.

17. A method comprising using magnesium oxide, an alkaline earth material, an alkali metal, a transitional metal, a precious metal, a noble metal, palladium, platinum, copper, cobalt and/or Hopcalite to adsorb NOx from an abatement gas stream and subsequently desorb said NOx for catalytic treatment.
